(19) United States
(12) Patent Application Publication
(10) Pub. No.: US 2005/0133086 A1
(43) Pub. Date: Jun. 23, 2005

(54) Solar cell module with conductor member and with bypass diode arranged on condcutor member, and method of producing same

(75) Inventors: Shigenori Itoyama, Sakata-gun (JP); Ichiro Kataoka, Hikone-shi (JP); Hidehisa Makita, Hikone-shi (JP); Masaaki Matsushita, Hikone-shi (JP); Takaaki Mukai, Hikone-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/009,004

(22) Filed: Dec. 13, 2004

(30) Foreign Application Priority Data
Dec. 19, 2003 (JP) 2003-422103

(51) Int. Cl. H01L 31/00

(52) U.S. Cl. 136/256; 136/252

(57) ABSTRACT

A solar cell module includes at least one photovoltaic element, bypass diodes for preventing a reverse voltage from being applied to the photovoltaic element, and a conductor member for arranging the bypass diode thereon, the conductor member being composed of a pair of connection portions on the photovoltaic element side, and plural routes of connection portions on the bypass diode side, the plural routes of the connection portions on the bypass diode side of the conductor member being arranged in parallel between the pair of the connection portions on the photovoltaic element side of the conductor member, and the bypass diodes being arranged in a zig-zag pattern in the neighboring routes so that the positions thereof are shifted from each other. The bypass diodes can be connected to the photovoltaic element without air-bubbles remaining.

### BACKGROUND OF THE INVENTION

1. Field of the Invention

The present invention relates to a solar cell module containing at least one photovoltaic element and a bypass diode for preventing a reverse voltage from being applied to the photovoltaic element.

2. Description of the Related Art

In recent years, environmental issues have been deeply recognized all over the world. Especially, the global warming phenomenon, caused by the CO₂ emission, has been severely apprehended. More nonpolluting energies have been required. Nowadays, solar cells are expected to be used as nonpolluting energy sources, since their safety is high, and they can be easily handled.

In recent years, a variety of configurations for solar cells have been proposed. Systems in which solar cell panels are fixed on stands disposed on roofs, and systems in which solar cells are integrated with building components, that is, systems in which solar cells are incorporated into the building components, have been developed in addition to systems in which solar cells are set on stands disposed on the ground.

Regarding solar cell modules, generally, a single photovoltaic element or a plurality of photovoltaic elements are sealed with a covering material. The light reception surface and the non-light-reception surface of a photovoltaic element are covered with a weather-resistant material. Photovoltaic elements are electrically connected in series and parallel combinations. Generally, the output power from a solar cell module is converted to AC voltage and is supplied to a power system.

If at least one of the photovoltaic elements arranged in a solar cell module as described above is in shadow, a reverse voltage is, in some cases, applied across both ends of the shadowed photovoltaic element.

FIG. 12 is a schematic view showing photovoltaic elements of a known type, one of which one is in shadow. In FIG. 12, photovoltaic elements 31, a shaded photovoltaic element 32, a solar cell module 33, and wiring 34 are shown.

As seen in FIG. 12, when the photovoltaic element 32 is in shadow, no current flows in the shaded photovoltaic element 32. The remaining photovoltaic elements 31, illuminated by sunlight, are made to pass current. Therefore, a reverse voltage is applied to the shaded photovoltaic element 32 through a load. Thus, in some cases, the shaded photovoltaic element 32 is damaged. To prevent such damage, bypass diodes are connected to each of the photovoltaic elements 31.

FIG. 13 schematically shows the cross-sectional structure of a photovoltaic element to which a conventional type of bypass diode is connected. FIG. 14 schematically shows the photovoltaic element of FIG. 13. In these drawings, the photovoltaic element 31, a bypass diode 41, a conductor member 42, a positive electrode 43, a semiconductor photovoltaic element activating layer 44, a conductive substrate 45, a collecting electrode 46, and solder 47 are shown.

In the case where the conductive substrate 45 of the photovoltaic element also functions as a back-side electrode, as shown in these drawings, the bypass diode 41 is electrically connected between the positive electrode 43 and the conductive substrate 45 of the photovoltaic element 31. The bypass diode 41 is connected in parallel to the photovoltaic element 31 via the conductor member 42. In particular, the cathode of the bypass diode 41 is connected to the positive electrode 43, so that the reverse current flowing through the photovoltaic element 31 can be rectified.

After the bypass diodes are provided for the photovoltaic elements 31 as described above, the photovoltaic elements 31 are connected in series or in parallel, if necessary, and are, then, sealed.

FIG. 15 schematically shows materials laminated on a conventional photovoltaic element so as to seal the photovoltaic element. FIG. 16 schematically shows the cross-sectional structure of a conventional solar cell module obtained after the solar cell module is integrally formed, so that the photovoltaic element is sealed. In these drawings, the photovoltaic element 31, the bypass diode 41, a sealing material 51, a front-surface covering material 52, and a back-surface covering material 53 are shown.

As shown in FIG. 15, the front-surface covering material 52, the sealing material 51, the photovoltaic element 31, the sealing material 51, and the back-surface covering material 53 are heated and pressed under reduced pressure. Thus, the photovoltaic element 31 can be sealed by the integral forming shown in FIG. 16.

As described above, the photovoltaic element 31 is sealed to form the solar cell module. Thus, the photovoltaic elements 31 can be used outdoors for a long period of time.

In the case where the conversion efficiency of the photovoltaic element 31 is high, so that a larger current can flow, the capacity of the bypass diode 41 becomes insufficient in some cases. In the case where a diode with larger capacity is selected as the diode 41, the volume of the diode 41 is large. Therefore, air-bubbles tend to remain in the solar cell module after the solar cell module is integrally formed to seal the photovoltaic element. Also, a film, if it is used as the front-surface covering material 52, tends to become creased. In particular, if air-bubbles remain in the solar cell module, water may remain in the air-bubbles while the module is used outdoors. This may cause an electric circuit contained in the solar cell module to be shorted and, also, an electrode material in the module to become rusted.

To cope with the above-described problems, plural diodes with small capacity and small volume may be arranged in parallel. For example, Japanese Patent Laid-Open 2000-243995 discloses a technique in which plural bypass diodes are electrically connected in parallel in order to allow an increased current to flow through a photovoltaic element.

The following systems by which plural bypass diodes are connected in parallel to a photovoltaic element may be proposed. That is, a pair of conductor members is prepared for one bypass diode. Plural sets each comprising the pair of conductor members and one bypass diode are fixed to a photovoltaic element. Alternatively, plural bypass diodes and one pair of conductor members are prepared, the bypass diodes are connected in parallel between the pair of conductor members, and the pair of conductor members is connected to a photovoltaic element in such a manner that the bypass diodes are connected in parallel to the photovoltaic element.

FIG. 17 schematically shows that a conventional conductor member having a parallel combination of plural diodes with small capacity is connected to a photovoltaic element in such a manner that the bypass diodes are connected in parallel to the photovoltaic element. FIG. 18 schematically shows the cross-sectional structure of a conventional solar cell module having plural bypass diodes with small capacity connected in parallel to a photovoltaic element and integrally formed so as to seal the photovoltaic element. In these drawings, the photovoltaic element 31, the bypass diodes 41, and the conductor member 42 are shown. Reference character d designates the distance between the side-edge of the photovoltaic element and the external side edge of the bypass diodes.

With the above-described configuration, sufficient degassing can be ensured, and moreover, the manufacturing cost is not increased. Furthermore, in the case where a film is used as the front-surface covering material 52, the film can be prevented from creasing.

The reduction of the manufacturing cost of solar cell modules is an urgent problem. Therefore, it is important to reduce the amount of a sealing material used in solar cell modules. In the case where the plural diodes 41 are connected in parallel as shown in FIG. 17, the area occupied by the bypass diodes 41 increases due to the plural bypass diodes 41 connected in parallel, but the manufacturing cost for the mounting process does not significantly change. As the area increases, the amount of a sealing material must be increased.

To reduce the amount of a sealing material to the smallest possible level, it is required to reduce the distance d between the side-edge of the photovoltaic element 31 and the external side edge of the bypass diode 41 positioned farthest from the photovoltaic element 31, and to reduce the distance between neighboring bypass diodes to the smallest possible level.

However, it has been found that when the plural diodes 41 are arranged adjacently to each other, the sealing material is insufficiently filled therebetween, so that air-bubbles remain in the sealing material.

### SUMMARY OF THE INVENTION

The present invention has been devised in view of the foregoing. It is an object of the present invention to provide a solar cell module in which plural bypass diodes for preventing the generation of reverse voltage are connected to a photovoltaic element, the plural bypass diode and the photovoltaic element are sealed without air bubbles remaining, and the solar cell module has a superior appearance and exhibiting a high reliability when it is used outdoors for a long period of time.

According to the present invention, there is provided a solar cell module which includes at least one photovoltaic element, bypass diodes for preventing a reverse voltage from being applied to the photovoltaic element, and a conductor member for arranging the bypass diodes thereon, the conductor member being composed of a pair of connection portions on the photovoltaic element side, and plural routes of connection portions on the bypass diode side, the connection portions on the bypass diode side in the two routes of the conductor member being arranged in parallel between the connection portions on the photovoltaic element side of the conductor member, and the bypass diodes being arranged in a zig-zag pattern in the neighboring routes so that the positions thereof are shifted from each other. Accordingly, the degassing during sealing is facilitated, so that a sealing material can flow smoothly. Thus, the photovoltaic element can be sealed without air bubbles remaining between the respective pieces of the solar cell module. The appearance of the solar cell module is superior, and the reliability thereof on the outdoor use for a long period of time is enhanced.

Preferably, a plurality of photovoltaic elements are electrically connected in series or in parallel to form a photovoltaic element group, and a conductor member is arranged so as to extend across neighboring photovoltaic elements. Even if one of the photovoltaic elements constituting the photovoltaic element group is in shadow, a reverse voltage can be prevented from being applied to the shaded photovoltaic element.

Also, preferably, a space is provided between the neighboring photovoltaic elements, and no bypass diodes exist within the space and the area extending from the space. If the solar cell module is bent between photovoltaic elements thereof, the bending stress is prevented from being applied to the bypass diodes.

In yet another aspect, the present invention relates to a solar cell module comprising at least one photovoltaic element, a plurality of bypass diodes for preventing a reverse voltage from being applied to the at least one photovoltaic element, and a conductor member having the plurality of bypass diodes arranged thereon, wherein the conductor member comprises a pair of connection portions each having an end connected to a photovoltaic element of the at least one photovoltaic element, and a plurality of connection routes arranged in parallel between the pair of connection portions, the plurality of connection routes including a first connection route and a second connection route that is a neighboring route with respect to the first connection route, wherein the plurality of bypass diodes comprises a first bypass diode and a second bypass diode, with the first bypass diode being arranged on the first connection route, and the second bypass diode being arranged on the second connection route, and wherein the first bypass diode and the second bypass diode are arranged in a pattern so that the positions thereof are shifted from each other in a direction along a line parallel to the plurality of connection routes.

In a still further aspect, the present invention relates to a solar cell module comprising at least one photovoltaic element, at least three bypass diodes for preventing a reverse voltage from being applied to the at least one photovoltaic element, and a conductor member having the at least three bypass diodes arranged thereon, wherein the conductor member comprises a pair of connection portions each having an end connected to a photovoltaic element of the at least one photovoltaic element, and a plurality of connection routes arranged in parallel between the pair of connection portions, the plurality of connection routes including a first connection route, a second connection route, and a third connection route, wherein there are no connection routes between the first connection route and the second connection route, and between the second connection route and the third connection route, wherein the at least three bypass diodes comprise a first bypass diode arranged on the first connection route, a second bypass diode arranged on the second connection route, and a third bypass diode arranged on the third connection route, and wherein the first bypass diode, the second bypass diode, and the third bypass diode are arranged in a zig-zag pattern.

In a still further aspect, the present invention relates to a solar cell module comprising at least one photovoltaic element, a pair of bypass diodes for preventing a reverse voltage from being applied to the at least one photovoltaic element, and a conductor member, wherein the conductor member comprises a first conducting component and a second conducting component, each of which is connected to a photovoltaic element of the at least one photovoltaic element, wherein the first conducting component comprises a first protruding portion and a second protruding portion arranged in parallel, and the second conducting component comprises a first protruding portion and a second protruding portion arranged in parallel, wherein one of the pair of bypass diodes bridges the first protruding portion of the first conducting component with the first protruding portion of the second conducting component, and the other of the pair of bypass diodes bridges the second protruding portion of the first conducting component with the second protruding portion of the second conducting component, and wherein the first protruding portion of the first conducting component has a length different from that of the second protruding portion of the first conducting component, and the first protruding portion of the second conducting component has a length different from that of the second protruding portion of the second conducting component.

In a still further aspect, the present invention relates to a solar cell module comprising at least one photovoltaic element, a pair of bypass diodes for preventing a reverse voltage from being applied to the at least one photovoltaic element, and a conductor member having two conducting components, each of which is connected to a photovoltaic element of the at least one photovoltaic element, wherein the two conducting components have different shapes and are bridged by the pair of bypass diodes.

In a still further aspect, the present invention relates to a method of producing a solar cell module comprising at least one photovoltaic element, a pair of bypass diodes for preventing a reverse voltage from being applied to the at least one photovoltaic element, and a conductor member having a first conducting component and a second conducting component, the method comprising the steps of: (a) forming the conductor member such that the first conducting component has a first protruding portion and a second protruding portion with a length different from that of the first protruding portion, and such that the second conducting component has a first protruding portion and a second protruding portion with a length different from that of the first protruding portion of the second conducting component; (b) arranging the pair of bypass diodes on the conductor member such that one of the pair of bypass diodes bridges the first protruding portion of the first conducting component with the first protruding portion of the second conducting component, and such that the other one of the pair of bypass diodes bridges the second protruding portion of the first conducting component with the second protruding portion of the second conducting component; and (c) sealing the at least one photovoltaic element, the pair of bypass diodes, and the conductor member with a sealing material.

Further objects, features and advantages of the present invention will become apparent from the following description of the preferred embodiments (with reference to the attached drawings).

### BRIEF DESCRIPTION OF THE DRAWINGS

FIG. 1 schematically shows a photovoltaic element constituting a solar cell module according to the present invention.

FIG. 2 schematically shows covering materials that are laminated to seal a photovoltaic element according to an embodiment of the present invention.

FIG. 3A is a schematic perspective view showing bypass diodes that are fixed on a conductor member according to an embodiment of the present invention.

FIG. 3B is a cross-sectional view showing the bypass diode to be fixed onto the conductor member.

FIG. 4A schematically shows the conductor member according to an embodiment of the present invention.

FIG. 4B shows the length between the connection portions on the bypass diode side of the conductor member.

FIG. 4C schematically shows the bypass diodes and the conductor electrode integrated with each other.

FIG. 5 schematically shows the cross-sectional structure of a photovoltaic element in Example 1.

FIG. 6 schematically shows the cross-sectional structure of the solar cell module obtained after the sealing is carried out in Example 1.

FIGS. 7A, 7B, and 7C show that bypass diodes and a conductor member are integrated with each other in Example 2.

FIG. 7A schematically shows a conductor member in Example 2.

FIG. 7B schematically shows the length between the connection portions on the bypass diode side of the conductor member.

FIG. 7C schematically shows the bypass diodes and the conductor member integrated with each other.

FIG. 8 schematically shows a photovoltaic element in Example 2.

FIG. 9 schematically shows the series-connection portion between photovoltaic elements in Example 3.

FIG. 10 is an enlarged schematic view showing the arrangement of the bypass diodes of FIG. 9.

FIGS. 11A and 11B illustrate the production of a solar cell module in Example 3. FIG. 11A schematically shows a plurality of photovoltaic elements connected in series. FIG. 11B schematically shows the plurality of photovoltaic elements connected in series to which a frame is fixed after the integral sealing is carried out.

FIG. 12 schematically shows conventional photovoltaic elements of which one is shaded.

FIG. 13 schematically shows the cross-sectional structure of a conventional photovoltaic element having a bypass diode connected thereto.

FIG. 14 schematically shows the photovoltaic element of FIG. 13.

FIG. 15 is a view for illustrating the lamination of materials for sealing the conventional photovoltaic element.

FIG. 16 schematically shows the cross-sectional structure of the conventional solar cell module obtained after the integral forming and sealing is carried out.

FIG. 17 schematically shows a photovoltaic element having a conductor member connected in parallel thereto, the conductor member having two conventional bypass diodes with small capacity connected in parallel.

FIG. 18 schematically shows the cross-sectional structure of the photovoltaic element having the plural conventional bypass diodes with small capacity connected in parallel thereto, obtained after the integral forming and sealing is carried out.

### DESCRIPTION OF THE EMBODIMENTS

Hereinafter, preferred embodiments for carrying out the present invention are described with reference to the drawings. The present invention is not restricted to the embodiments, however.

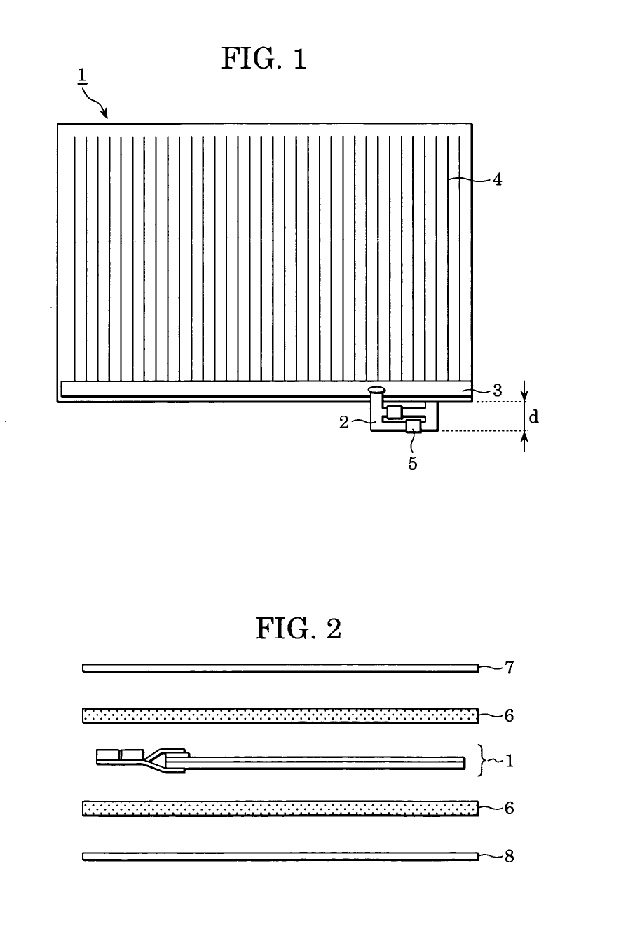

FIG. 1 schematically shows a photovoltaic element constituting a solar cell module according to an embodiment of the present invention. In FIG. 1, a photovoltaic element 1, a conductor member 2, a positive electrode 3 of the photovoltaic element 1, a collector electrode 4, and a bypass diode 5 are shown.

As shown in FIG. 1, the photovoltaic element 1 according to this embodiment contains a conductive sheet as a substrate (not shown). The substrate is used as a back-surface electrode. A semiconductor layer (not shown) is formed on the back-surface electrode. Then, the positive electrode 3 is formed on the end portion of the photovoltaic element. According to this embodiment, for example, two bypass diodes 5 are connected in parallel. These bypass diodes 5 are arranged in a zig-zag pattern on the conductor member 2 with the positions of the bypass diodes 5 being shifted from each other on the conductor member 2, so as to be electrically connected to the conductor member 2. After the conductor member 2 and the bypass diodes 5 are integrated with each other, the conductor member 2 is electrically connected to the positive electrode 3 of the photovoltaic element 1 and to the substrate thereof. The photovoltaic element 1 produced as described above is sealed with covering materials in such a manner that the photovoltaic element 1 and the sealing materials are integrated.

FIG. 2 schematically shows the lamination of the covering materials for sealing of the photovoltaic element according to this embodiment. In FIG. 2, the photovoltaic element 1, a sealing material 6, a front-surface covering material 7, and a back-surface covering material 8 are shown. The front-surface covering material 7, the sealing material 6, the photovoltaic element 1, the sealing material 6, and the back-surface covering material 8 are laminated in that order. These materials are heated and pressed under reduced pressure so as to be integrated. The sizes in both of the longitudinal and transverse directions of each covering material are larger than those of the photovoltaic element 1.

The respective constituents of the solar cell module of this embodiment are described in detail below.

Photovoltaic Element

The material for the photovoltaic element 1 has no particular limitations. For example, photovoltaic elements in which amorphous crystal silicon and microcrystal silicon are laminated, crystal silicon photovoltaic elements, polycrystal photovoltaic elements, amorphous silicon photovoltaic elements, copper indium selenide photovoltaic elements, compound semiconductor photovoltaic elements, or the like may be used as the photovoltaic element 1. Thin film photovoltaic elements are flexible, and thus, are preferred for the production of photovoltaic elements with large areas. In particular, a photovoltaic element in which a semiconductor activating layer or the like serving as a photo-conversion member is formed on a flexible electroconductive substrate is preferable, since the photovoltaic element can be easily formed so as to have a large area and have a high reliability under bending stress. For example, a laminated-type photovoltaic element which is an amorphous microcrystal silicon type and includes a three-layer structure is especially preferable.

The electrical properties (voltage, output, and so forth) of a single photovoltaic element have limitations. Accordingly, a plurality of photovoltaic elements are electrically connected in parallel or in series so as to attain a desired electrical property. The plurality of photovoltaic elements connected as described above is called a photovoltaic element group. Each photovoltaic element is provided with positive and negative electrodes, so that the photovoltaic elements can be connected in series or in parallel.

Bypass Diode

A single photovoltaic element or a photovoltaic element group is provided with bypass diodes. That is, bypass diodes 5 are connected in parallel to each photovoltaic element so that a reverse voltage can be prevented from being applied to a photovoltaic element when the photovoltaic element is shielded from light. The type of the bypass diodes 5 has no particular limitations. General-use rectifier silicone diodes, Schottky barrier diodes, and so forth may be used as the bypass diodes 5.

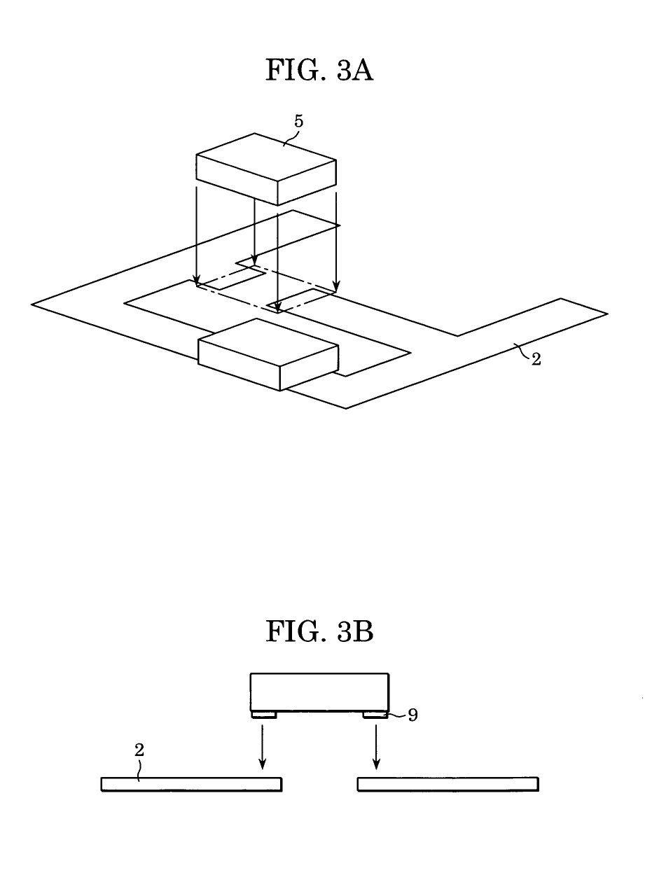

FIG. 3A is a schematic perspective view showing the bypass diodes 5 that are fixed onto the conductor member 2. FIG. 3B schematically shows that the bypass diode tends to be fixed onto the conductor member. In FIGS. 3A and 3B, the bypass diodes 5, the conductor member 2, and the electrodes 9 of the bypass diode 5 are shown.

As shown in FIGS. 3A and 3B, the electrodes 9 of each bypass diode 5 are positioned on the conductor member 2 and electrically connected to the conductor member 2. Generally, solder is applied for the electrical connection.

Diodes have a current rating. The bonding temperature for each diode has an upper limit. Thus, the diode must be used below the bonding temperature. If a current larger that the rated current flows through the diode, the temperature of the diode rises to be higher than the bonding temperature, and the diode may fail. Therefore, the area of the bonding portion of the diode is increased to enhance the current rating. In other words, it is necessary to arrange diodes in parallel so as to have a large area. Accordingly, the volume of the diodes increases due to the enhancement of the current rating.

Thus, to prepare for larger current flowing through the photovoltaic element 1 compared to the rated current of the diode, plural bypass diodes having a low current rating are arranged in parallel, instead of using a bypass diode having a high current rating. In this way, degassing can be performed more efficiently while the photovoltaic element is sealed by the integral forming. Thus, the photovoltaic element 1 can be sealed more satisfactorily.

Conductor Member

According to this embodiment, the conductor member 2 is used as a wiring member for electrically connecting the bypass diodes 5 between the positive electrode and the negative electrode of the photovoltaic element 1. For the purpose of sufficiently sealing the bypass diodes 5 with a sealing material, copper foil is often used as the sealing material. However, the sealing material is not restricted to copper foil. Referring to the electrical connection of the bypass diodes 5 to the photovoltaic element 1, first, the bypass diodes 5 and the conductor member 2 are integrated in advance, and then, the conductor member 2 is electrically connected to the photovoltaic element 1. Regarding the conductor member 2 that is connected to the anode and the cathode of each bypass diode 5, it is convenient to form the conductor member 2 in such a shape and size that the bypass diodes 5 can be arranged in a zig-zag pattern with the positions of the bypass diodes 5 being shifted from each other.

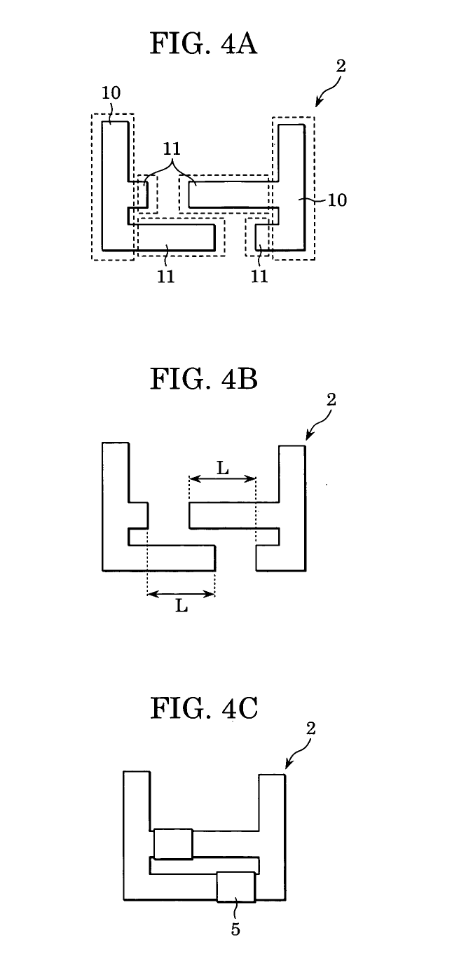

FIGS. 4A, 4B, and 4C illustrate the integration of the bypass diodes and the conductor member. FIG. 4A schematically shows the conductor member. FIG. 4B is a schematic view showing the lengths between the connection portions of the bypass diodes. FIG. 4C is a schematic view of the diodes and the conductor members integrated with each other. In FIGS. 4A, 4B, and 4C, the conductor member 2, the bypass diodes 5, the connection portions 10 on the photovoltaic element side of the conductor member, and the connection portions 11 on the bypass diode side of the conductor member are shown.

As shown in FIGS. 4A, 4B, and 4C, the conductor member 2 contains a pair of the connection portions 10 on the photovoltaic element side and two routes defined by the connection portions 11 on the bypass diode side. The two routes defined by the connection portions 11 are arranged in parallel to each other between the pair of the connection portions 10 and 10 on the photovoltaic element side. A difference L in length is provided between the connection portions 11 and 11 on the bypass diode side, as shown in FIG. 4B, so that the bypass diodes 5 can be disposed in a zig-zag pattern with the positions thereof being shifted from each other. For example, the bypass diodes 5 can be disposed in a zig-zag pattern with the positions thereof being shifted from each other by setting the difference L to be larger than the length of the bypass diodes 5. The bypass diodes 5 and the conductor member 2 are electrically connected, e.g., by soldering, as described above.

Arrangement of Bypass Diodes

In this invention, the expression “the arrangement in a zig-zag pattern of the bypass diodes” means that bypass diodes of one set connected in parallel to one photovoltaic element are arranged separately from each other, in a zig-zag pattern while the positions thereof are shifted from each other, as viewed from the light-reception surface side of the photovoltaic element.

The above-described arrangement of the bypass diodes can be achieved by setting the length of a connection portion 11 contained in one route so as to be different from the length of the connection portion 11 contained in the other route and extended in parallel to the above-described connection portion 11.

Preferably, the difference L in length between the above-described connection portions of the conductor member 2 is larger than the length of the bypass diode itself in the direction in which the connection portions of the two routes are extended in parallel. In particular, in the case where each bypass diode has a rectangular shape, it is preferred that the shortest distance between the bypass diodes positioned closest to each other be equal to the distance between the neighboring apexes of the rectangles.

In the case where a plurality of photovoltaic elements 1 are electrically connected in series or in parallel to form a photovoltaic element group, an interval or space is provided between neighboring photovoltaic elements. Preferably, no bypass diodes are positioned in the space and the area extending from the space. Thus, even if the solar cell module is bent between the neighboring photovoltaic elements, the stress can be prevented from being applied to the bypass diodes 5. Problems such as failure of the bypass diodes can thus be eliminated.

As described above, according to this embodiment, a plurality of photovoltaic elements are electrically connected in series or in parallel to form a photovoltaic element group, and a conductor member 2 is disposed so as to extend over neighboring photovoltaic elements. Therefore, even if any one of the photovoltaic elements contained in the photovoltaic element group is shaded, a reverse voltage can be prevented from being applied to the shadowed photovoltaic element 1.

Although the plural bypass diodes 5 having a small capacity are connected in parallel, the amount of the sealing material 6 used can be reduced by arranging the neighboring bypass diodes 5 on the conductor member 2 in a zig-zag pattern.

As described above, the neighboring bypass diodes 5 are arranged on the conductor member 2 in a zig-zag pattern. This facilitates degassing in the area near the bypass diodes 5, so that the sealing material 6 can flow more smoothly between the pieces to be sealed. Therefore, the photovoltaic element 1 can be sealed without air bubbles remaining therein. Thus, the appearance of the solar cell module becomes satisfactory, and also, the reliability of the solar cell module exhibited when it is used outdoors for a long period of time can be enhanced.

Hereinafter, examples according to the present invention will be described in detail. However, the present invention is not restricted to the examples.

### EXAMPLE 1

In a solar cell module of Example 1, the two bypass diodes 5 were electrically connected in parallel to the photovoltaic element. The covering materials on the front-surface side and the back-surface side of the solar cell module were made of weather-resistant films.

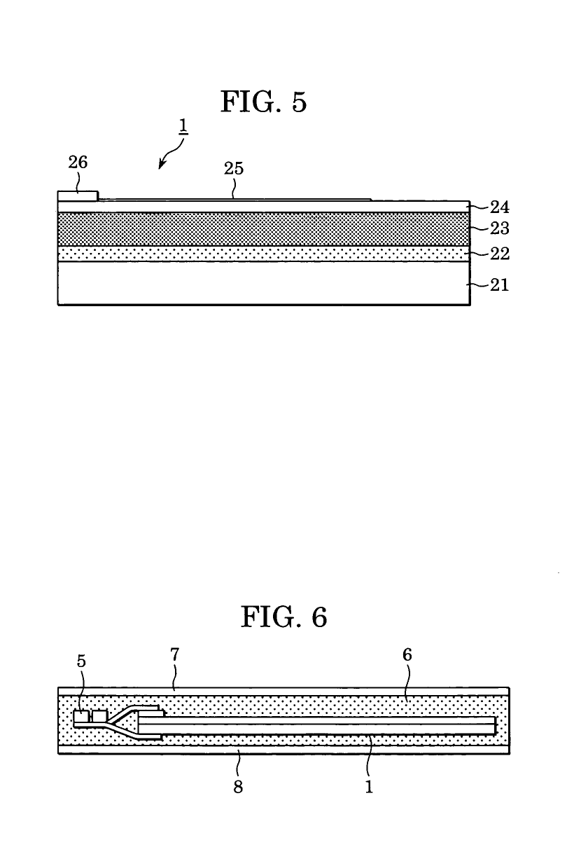

FIG. 5 schematically shows the cross-sectional structure of a photovoltaic element in Example 1. In FIG. 5, the photovoltaic element 1, a conductive substrate 21, a metallic electrode layer 22, a semiconductor photo-activation layer 23, a transparent conductive layer 24, a collector electrode 25, and a positive electrode 26 are shown.

As shown in FIG. 5, in the photovoltaic element 1 of Example 1, a stainless steel sheet was used as the conductive substrate 21. An Al layer and a ZnO layer were sequentially formed on the metallic electrode layer 22 on the back-surface side thereof. Thereby, the metal electrode layer 22 was formed. Moreover, an n-type-a-Si layer, an i-type-a-Si layer, a p-type microcrystal μc-Si layer, and an a-Si type semiconductor activation layer 23 were formed thereon. Then, an In₂O₃ thin film was formed thereon to produce the transparent conductive layer 24. Thereafter, the collector electrode 25 was formed by screen-printing silver-containing paste, and drying it. Finally, the positive electrode 26 was formed on the end portion of the photovoltaic element 1. Thus, the photovoltaic element 1 was produced.

The photovoltaic element 1 with a size of 240 mm×360 mm was produced as described above. The current rating of the photovoltaic elements 1 per one sheet was 10A.

Subsequently, the bypass diodes and the conductor member were integrated with each other. As shown in FIG. 4, two bypass diodes 5 with a rating of 5A (size of 2.5 mm in width×4 mm in length) were used. The conductor member 2 was formed by cutting copper foil with a size of 0.1 mm in thickness×2.5 mm in width into the shape shown in FIGS. 4A and 4B. The bypass diodes 5 and the conductor member 2 were integrated by soldering. Reference character L represents the difference between the lengths of the connection portions 11 on the bypass diode side of the conductor member 2. In Example 1, the length L was set at 8 mm. As described above, the length of each bypass diode 5 was 4 mm. Therefore, the two bypass diodes could be arranged in a zig-zag pattern so that the positions thereof were shifted from each other.

Subsequently, the conductor member 2 having the bypass diodes 5 fixed thereon was electrically connected to the photovoltaic element 1. As seen in FIG. 1 and FIG. 4C, one of the connection portions 10 on the photovoltaic element side of the conductor member 2 was electrically connected to the positive electrode 26. The other connection portion is electrically connected to the conductive substrate 21. In this case, the conductor member 2 was electrically connected to the photovoltaic element in such a manner that the distance d (see FIG. 1) between the edge of the photovoltaic element 1 and the external edge of the bypass diode 5 positioned farther from the above-described edge of the photovoltaic element 1 was 8 mm. Moreover, in this case, the connection portion of the conductor member 2 on the cathode side of the bypass diodes 5 was connected to the positive electrode 26 of the photovoltaic element 1.

Subsequently, the photovoltaic element 1 produced as described above was sealed as shown in FIG. 2. In Example 1, EVA was used as the sealing material 6. A film made of fluoro-resin and a polyester film were used as the front-surface covering material 7 and the back-surface covering material 8, respectively. The respective covering materials had a size of 270 mm×380 mm. As seen in FIG. 2, the back-surface covering material 8, the sealing material 6, the photovoltaic element 1 produced as described above, the sealing material 6, and the front-surface covering material 7 were laminated in that order. These materials were heated and pressed under reduced pressure to seal the photovoltaic element 1.

FIG. 6 schematically shows the cross-sectional structure of the solar cell module obtained after the sealing was carried out in Example 1. In FIG. 6, the photovoltaic element 1, the bypass diodes 5, the sealing material 6, the front-surface covering material 7, and the back-surface covering material 8 are shown. The sealed solar cell module had a good finished appearance without air-bubbles contained therein.

Since the neighboring bypass diodes 5 were arranged in a zig-zag pattern on the conductor member so that the positions thereof were shifted from each other, as described above, the degassing could be easily achieved while the integral forming was carried out, so that the sealing materials 6 could flow smoothly, and the photovoltaic element 1 could be sealed without air-bubbles remaining. Thus, the appearance of the solar cell module was not only improved, but also the reliability of the solar cell module when used outdoors for a long period of time could be enhanced.

### EXAMPLE 2

In a solar cell module of Example 2, three bypass diodes 5 were electrically connected in parallel to a photovoltaic element. The front-surface covering material was made of glass, and the back-surface covering material was made of a film.

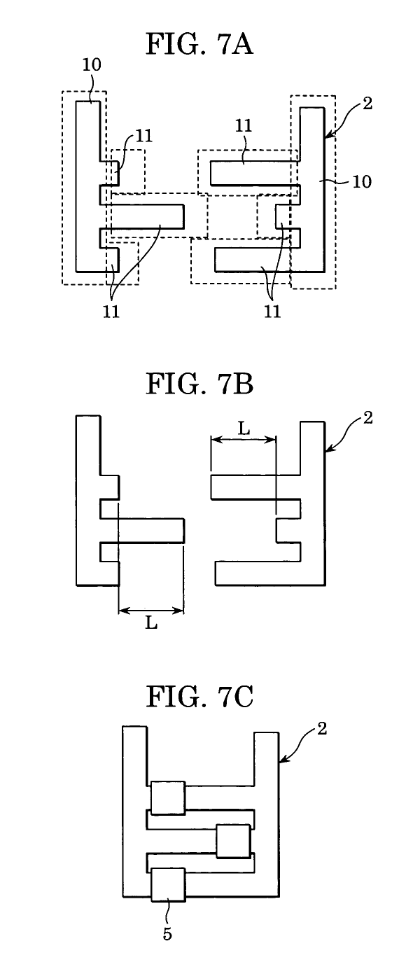

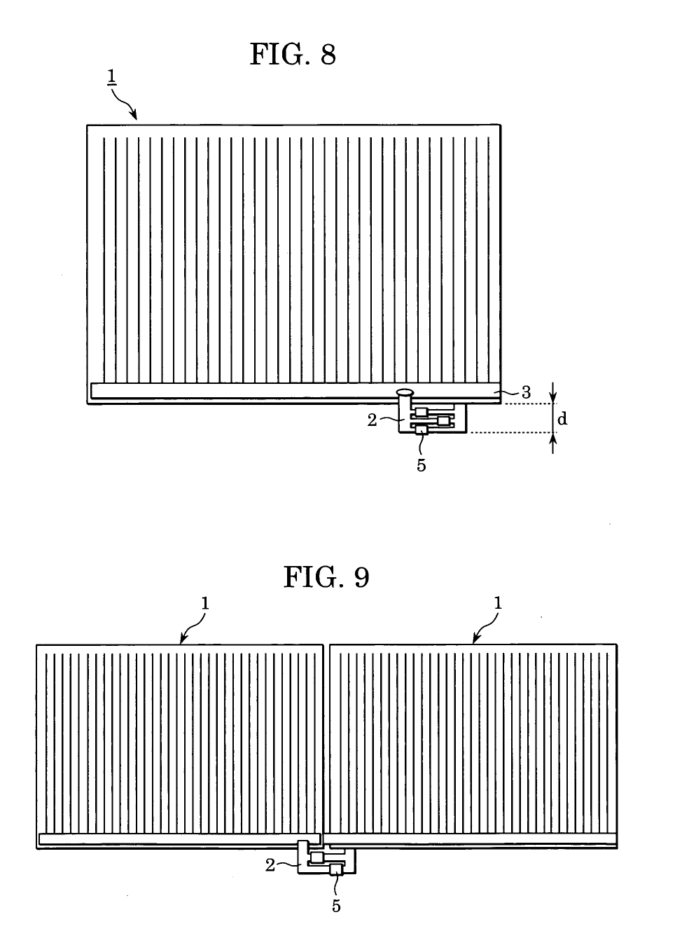

FIGS. 7A, 7B, and 7C show that the bypass diodes and a conductor member were integrated in Example 2. FIG. 7A shows the conductor member. FIG. 7B schematically shows the lengths of the connection portions 11 on the bypass diode side of the conductor member. FIG. 7C shows the bypass diodes and the conductor member integrated with each other. In FIGS. 7A, 7B, and 7C, the conductor member 2, the bypass diode 5, the connection portions 10 on the photovoltaic element side of the conductor member 2, and the connection portions 11 on the bypass diode side of the conductor member 2 are shown.

The bypass diodes 5 in Example 2 had a current rating of 3.5A (size of 2.0 mm in width×3 mm in length). The conductor member 2 was copper foil having a thickness of 0.1 mm and a width of 2.0 mm. The copper foil was cut into the shape shown in FIG. 7A in advance. The conductor member 2 was integrated with the bypass diodes 5 by soldering. In FIGS. 7A and 7B, reference character L represents the difference in length between the connection portions on the bypass diode side of the conductor member 2. In Example 2, the difference was set at 6 mm. The length of each bypass diode 5 was 3 mm. Therefore, the bypass diodes 5 could be arranged in a zig-zag pattern so that the positions thereof were shifted from each other.

Subsequently, the conductor member 2 having the bypass diodes 5 fixed thereon was electrically connected to the photovoltaic element 1. The photovoltaic element produced as described in Example 1 was employed.

FIG. 8 schematically shows the photovoltaic element in Example 2. In FIG. 8, the photovoltaic element 1, the conductor member 2, the positive electrode 3, and the bypass diode 5 are shown.

As shown in FIG. 8, one of the connection portions 10 on the photovoltaic element side of the conductor member 2 was electrically connected to the positive electrode 3. The other connection portion 10 was electrically connected to the conductive substrate (not shown). In this case, the conductor member 2 was connected to the photovoltaic element 1 in such a manner that the distance d between the edge on the connection side of the photovoltaic element 1 and the external edge of the bypass diode positioned farthest from the edge of the photovoltaic element 1 was 12 mm. Moreover, the connection portion of the conductor member 2 positioned on the cathode side of the bypass diodes 5 was electrically connected to the positive electrode 3 of the photovoltaic element 1.

Subsequently, the photovoltaic element 1 produced as described above was sealed. The materials for the respective members used in Example 2 were the same as those in Example 1 except that a glass sheet was used as the front-surface covering material 7. The respective covering materials had a size of 275 mm×380 mm. As shown in FIG. 2, the back-surface covering material 8, the sealing material 6, the photovoltaic element 1 produced as described above, the sealing material 6, and the front-surface covering material 7 were laminated in that order, and then, were heated and pressed under reduced pressure to seal the photovoltaic element 1.

As described above, in the case where the three diodes 5 were connected in parallel, a solar cell module having a good finished appearance without air-bubbles remaining could be also produced by arranging the three bypass diodes in a zig-zag pattern so that the positions of the bypass diodes were shifted from each other.

### EXAMPLE 3

In a solar cell module of Example 3, a plurality of photovoltaic elements were electrically connected in series to form a photovoltaic element group. Each conductive member 2 having the bypass diodes 5 arranged in parallel thereon were disposed so as to extend over neighboring photovoltaic elements. The photovoltaic element group was integrally sealed, and a frame was fixed to the surrounding edge of the sealed photovoltaic element group.

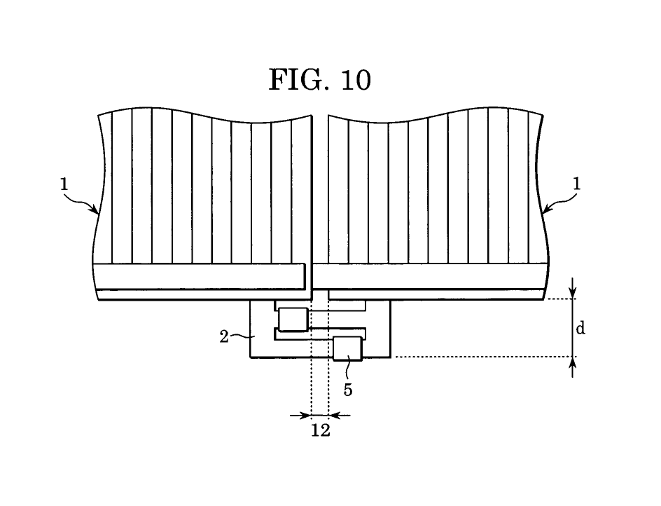

FIG. 9 schematically shows the series-connection portion of photovoltaic elements in Example 3. FIG. 10 is an enlarged schematic view showing the arrangement of the bypass diode of FIG. 9. In these drawings, the photovoltaic elements 1 and the bypass diodes 5 are shown. Reference numeral 12 represents an area extending from the space between neighboring photovoltaic elements.

As shown in the drawings, two photovoltaic elements 1 were arranged in series. The conductor member 2 was positioned so as to extend over the area 12 extending from the space between the photovoltaic elements. A parallel combination of two bypass diodes 5 was fixed on the conductor member 2. The length of the space between the photovoltaic elements was 5 mm.

The bypass diodes in Example 3 were the same as those in Example 1. The difference L (see FIG. 4C) in length between the connection portions on the bypass diode side of the conductor member 2 was set at 12 mm. Thereby, the conductor member 2 could be arranged in such a manner that the bypass diodes 5 are prevented from positioning within the area 12 extending from the space between the photovoltaic elements. Moreover, in the photovoltaic elements 1 of Example 3, the conductive substrate also functioned as a negative electrode. Therefore, both of the anode and the cathode of the conductor member 2 were electrically connected directly to the conductive substrates of the photovoltaic elements 1. The distance d between the edge on the bypass diode side of each photovoltaic element 1 and the external edge of the bypass diode positioned farthest from the edge of the photovoltaic element 1 was 8 mm, which was the same as that in Example 1.

Subsequently, a plurality of photovoltaic elements 1 were connected in series to form a photovoltaic element group in the same manner as described above. Thus, a solar cell module having a large area was produced.

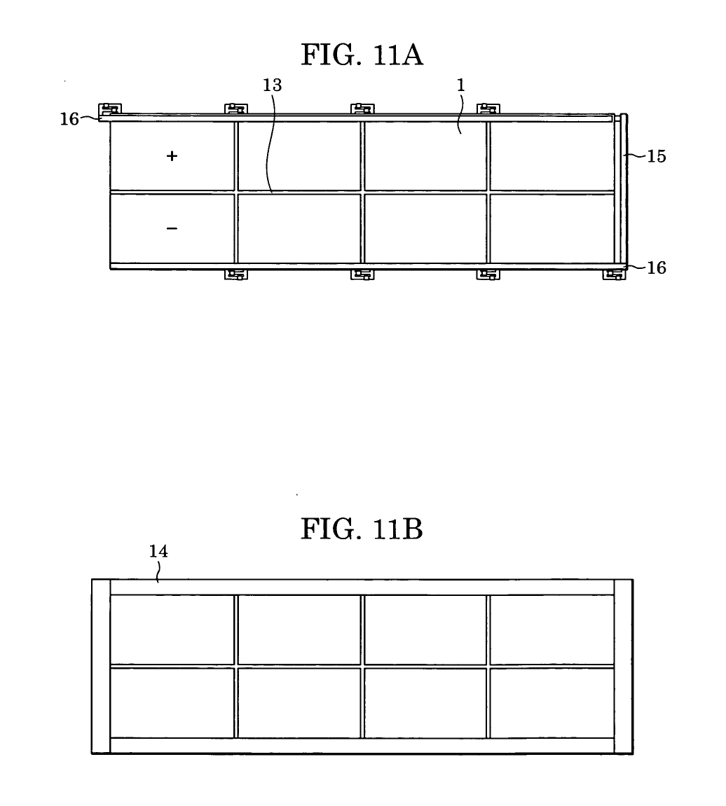

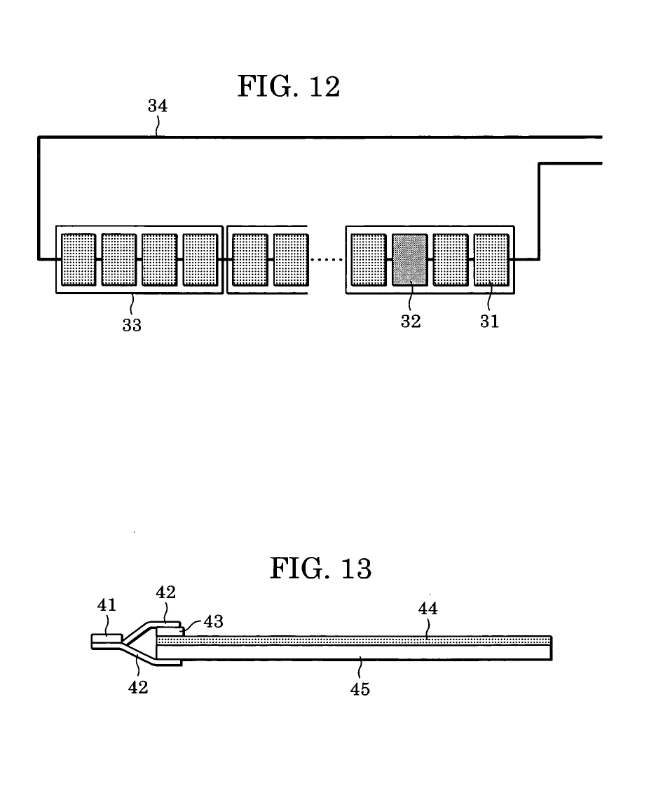

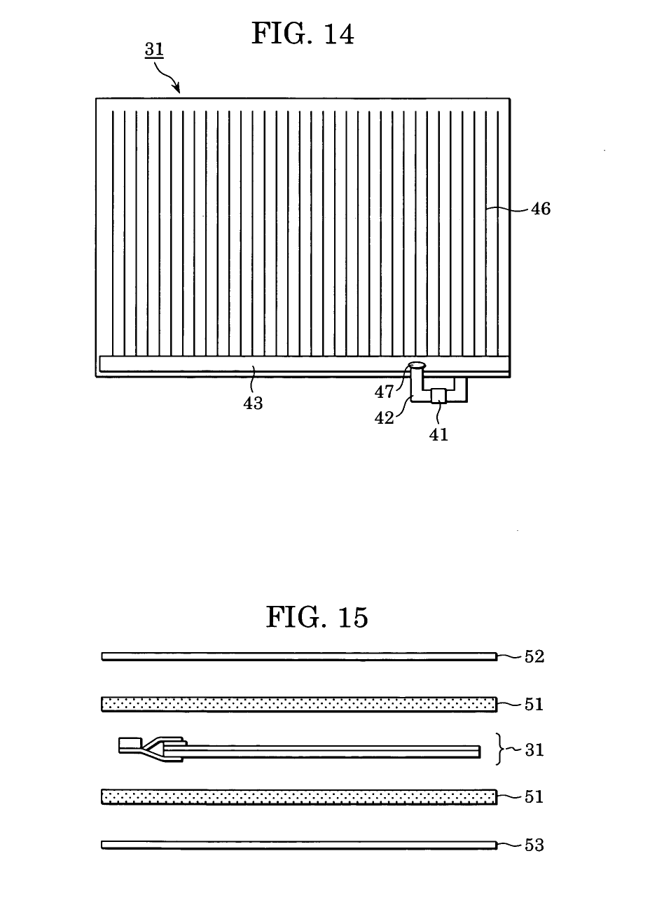

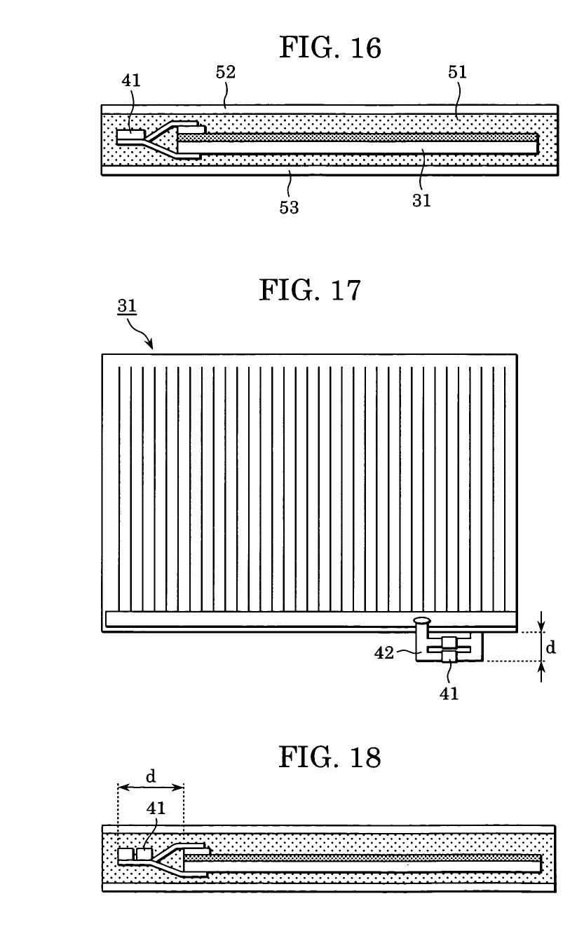

FIGS. 11A and 11B show the formation of the solar cell module of Example 3. FIG. 11A schematically shows a plurality of photovoltaic elements connected in series. FIG. 11B schematically shows the photovoltaic element group obtained after the integral sealing was carried out, and then, a frame is fixed thereto. In FIGS. 11A and 11B, the photovoltaic elements 1, the space 13 between neighboring photovoltaic elements, the frame 14, a connecting electrode 15 for the series-connection of photovoltaic elements which were “U-turned” to be connected with each other, and an extension portion 16 of the positive electrode are shown.

As shown in FIG. 11A, four photovoltaic elements 1 were connected in series to form one series-combination of the photovoltaic elements. Two series-combinations were arranged in parallel. One of the series-combinations was connected in series with the other series-combination in such manner that the one series-combination was “U-turned”. In the “U-turn” portion for the series-connection, a connecting electrode 15 was used so that the two series-combinations were connected in series. In the end of the one series-combination, the positive electrode was extended. The bypass diodes 5 were electrically connected between the prolonged portion 16 and the conductive substrate of the other series-combination. Thus, the bypass diodes 5 were connected to the photovoltaic elements 1 in the above-described manner, respectively.

After a plurality of the photovoltaic elements 1 were connected in series, the formed photovoltaic element group was sealed. The respective covering materials had a size of 505 mm×1475 mm. The sealing was carried out in the same manner as that in Example 1 except for the size of the covering materials.

Finally, as shown in FIG. 11B, the frame 14 was fixed to the surrounding portion of the photovoltaic element group. Thus, the solar cell module was produced.

In the case where a plurality of photovoltaic elements were connected in series to form a photovoltaic element group as described above, the bypass diodes 5 could be arranged so as to extend over the space 13 between neighboring photovoltaic elements. Moreover, the bypass diodes were arranged so as not to exist within the area 12 extending from the space. Therefore, when the solar cell module was bent between photovoltaic elements, the bending stress could be prevented from being applied to the bypass diodes 5. Thus, problems such as breaking of the bypass diodes could be eliminated.

In Example 3, the bypass diodes 5 were provided on one side only of the respective photovoltaic elements 1. Thus, one series-combination of the photovoltaic elements and the other series-combination could be arranged in such a manner that the side of one of the series-combinations where no bypass diodes were provided abutted on the side of the other series-combination where no bypass diodes were provided. Thus, the distance between the two series-combinations of the photovoltaic elements extended in parallel to each other could be set at a minimum. Moreover, with the above-described configuration, the respective bypass diodes 5 could be arranged in areas where the bypass diodes 5 could be shielded from light. In ordinary cases, it is necessary to provide an area shielded from light by the frame 14 between the solar cell module and the frame 14. Moreover, in the case where the plural series-combinations of photovoltaic elements were connected in series through the above-described “U-turn” portion, so that a solar cell module having a large area, the amount of the sealing material used could be considerably reduced.

While the present invention has been described with reference to what are presently considered to be the preferred embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadest interpretation so as to encompass all such modifications and equivalent structures and functions.

This application claims priority from Japanese Patent Application No. 2003-422103 filed Dec. 19, 2003, which is hereby incorporated by reference herein.

1. A solar cell module comprising:
at least one photovoltaic element;
a plurality of bypass diodes for preventing a reverse voltage from being applied to said at least one photovoltaic element; and
a conductor member having said plurality of bypass diodes arranged thereon,
wherein said conductor member comprises a pair of connection portions each having an end connected to a photovoltaic element of said at least one photovoltaic element, and a plurality of connection routes arranged in parallel between said pair of connection portions, said plurality of connection routes including a first connection route and a second connection route that is a neighboring route with respect to said first connection route,
wherein said plurality of bypass diodes comprises a first bypass diode and a second bypass diode, with said first bypass diode being arranged on said first connection route, and said second bypass diode being arranged on said second connection route, and
wherein said first bypass diode and said second bypass diode are arranged in a pattern so that the positions thereof are shifted from each other in a direction along a line parallel to said plurality of connection routes.

2. The solar cell module according to claim 1, wherein said ends of said pair of connection portions are connected to the same photovoltaic element.

3. The solar cell module according to claim 1, wherein said at least one photovoltaic element is a plurality of photovoltaic elements electrically connected in series or in parallel to form a photovoltaic element group, and wherein said conductor member is arranged so as to extend across neighboring photovoltaic elements.

4. The solar cell module according to claim 3, wherein a space is provided between the neighboring photovoltaic elements, and no bypass diodes exist within the space or the area extending from the space.

5. The solar cell module according to claim 1, wherein no line drawn perpendicular to said plurality of connection routes intersects both said first bypass diode and said second bypass diode.

6. The solar cell module according to claim 1, wherein said first bypass diode and said second bypass diode each have a rectangular shape, and wherein the shortest distance between said first bypass diode and said second bypass diode is equal to the distance between a corner of said first bypass diode and a corner of said second bypass diode.

7. A solar cell module comprising:
at least one photovoltaic element;
at least three bypass diodes for preventing a reverse voltage from being applied to said at least one photovoltaic element; and
a conductor member having said at least three bypass diodes arranged thereon,
wherein said conductor member comprises a pair of connection portions each having an end connected to a photovoltaic element of said at least one photovoltaic element, and a plurality of connection routes arranged in parallel between said pair of connection portions, said plurality of connection routes including a first connection route, a second connection route, and a third connection route,
wherein there are no connection routes between said first connection route and said second connection route, and between said second connection route and said third connection route,
wherein said at least three bypass diodes comprise a first bypass diode arranged on said first connection route, a second bypass diode arranged on said second connection route, and a third bypass diode arranged on said third connection route, and
wherein said first bypass diode, said second bypass diode, and said third bypass diode are arranged in a zig-zag pattern.

8. The solar cell module according to claim 7, wherein said ends of said pair of connection portions are both connected to the same photovoltaic element.

9. The solar cell module according to claim 7, wherein said at least one photovoltaic element is a plurality of photovoltaic elements electrically connected in series or in parallel to form a photovoltaic element group, and wherein said conductor member is arranged so as to extend across neighboring photovoltaic elements.

10. The solar cell module according to claim 9, wherein a space is provided between the neighboring photovoltaic elements, and no bypass diodes exist within the space or the area extending from the space.

11. The solar cell module according to claim 7, wherein no line drawn perpendicular to said plurality of connection routes intersects said first bypass diode, said second bypass diode, and said third bypass diode.

12. The solar cell module according to claim 7, wherein said first bypass diode, said second bypass diode, and said third bypass diode each have a rectangular shape, wherein the shortest distance between said first bypass diode and said second bypass diode is equal to the distance between a corner of said first bypass diode and a corner of said second bypass diode, and wherein the shortest distance between said second bypass diode and said third bypass diode is equal to the distance between a corner of said second bypass diode and said third bypass diode,

13. A solar cell module comprising:
at least one photovoltaic element;
a pair of bypass diodes for preventing a reverse voltage from being applied to said at least one photovoltaic element; and
a conductor member,
wherein said conductor member comprises a first conducting component and a second conducting component, each of which is connected to a photovoltaic element of said at least one photovoltaic element,
wherein said first conducting component comprises a first protruding portion and a second protruding portion arranged in parallel, and said second conducting component comprises a first protruding portion and a second protruding portion arranged in parallel,
wherein one of said pair of bypass diodes bridges said first protruding portion of said first conducting component with said first protruding portion of said second conducting component, and the other of said pair of bypass diodes bridges said second protruding portion of said first conducting component with said second protruding portion of said second conducting component, and
wherein said first protruding portion of said first conducting component has a length different from that of said second protruding portion of said first conducting component, and said first protruding portion of said second conducting component has a length different from that of said second protruding portion of said second conducting component.

14. The solar cell module according to claim 13, wherein said at least one photovoltaic element is a plurality of photovoltaic elements electrically connected in series or in parallel to form a photovoltaic element group, and wherein said conductor member is arranged so as to extend across neighboring photovoltaic elements.

15. The solar cell module according to claim 14, wherein a space is provided between the neighboring photovoltaic elements, and no bypass diodes exist within the space or the area extending from the space.

16. The solar cell module according to claim 13, wherein each of said pair of bypass diodes has a rectangular shape, and wherein the shortest distance between said pair of bypass diodes is equal to the distance between a corner of one of said pair of bypass diodes and a corner of the other of said pair of bypass diodes.

17. A solar cell module comprising:
at least one photovoltaic element;
a pair of bypass diodes for preventing a reverse voltage from being applied to said at least one photovoltaic element; and
a conductor member having two conducting components, each of which is connected to a photovoltaic element of said at least one photovoltaic element,
wherein said two conducting components have different shapes and are bridged by said pair of bypass diodes.

18. The solar cell module according to claim 17, wherein said pair of bypass diodes bridge said two conducting components at two different places.

19. A method of producing a solar cell module comprising at least one photovoltaic element, a pair of bypass diodes for preventing a reverse voltage from being applied to said at least one photovoltaic element, and a conductor member having a first conducting component and a second conducting component, the method comprising the steps of:
forming said conductor member such that said first conducting component has a first protruding portion and a second protruding portion with a length different from that of said first protruding portion, and such that said second conducting component has a first protruding portion and a second protruding portion with a length different from that of said first protruding portion of said second conducting component;
arranging said pair of bypass diodes on said conductor member such that one of said pair of bypass diodes bridges said first protruding portion of said first conducting component with said first protruding portion of said second conducting component, and such that said other one of said pair of bypass diodes bridges said second protruding portion of said first conducting component with said second protruding portion of said second conducting component; and
sealing said at least one photovoltaic element, said pair of bypass diodes, and said conductor member with a sealing material.

20. The method according to claim 19, wherein each of said pair of bypass diodes has a rectangular shape, and wherein said pair of bypass diodes is arranged such that the shortest distance between said pair of bypass diodes is equal to the distance between a corner of one of said pair of bypass diodes and a corner of the other of said pair of bypass diodes.

21. The method according to claim 19, wherein said at least one photovoltaic element is a plurality of photovoltaic elements electrically connected in series or in parallel to form a photovoltaic element group, and wherein said conductor member is arranged so as to extend across neighboring photovoltaic elements.

22. The method according to claim 21, wherein a space is provided between the neighboring photovoltaic elements, and wherein no bypass diodes exist within the space of the area extending from the space.
